(19) United States
(12) Patent Application Publication
(10) Pub. No.: US 2025/0111879 A1
(43) Pub. Date: Apr. 3, 2025

(54) PROGRAM OPERATIONS IN MEMORY DEVICES

(71) Applicant: Yangtze Memory Technologies Co., Ltd., Wuhan (CN)

(72) Inventors: Hongtao LIU, Wuhan (CN); Xiangnan ZHAO, Wuhan (CN); Ying HUANG, Wuhan (CN); Lei GUAN, Wuhan (CN)

(21) Appl. No.: 18/513,162

(22) Filed: Nov. 17, 2023

(30) Foreign Application Priority Data
Sep. 28, 2023 (CN) 202311292935.7

(51) Int. Cl. G11C 16/10; G11C 16/04; G11C 16/08; G11C 16/24

(52) U.S. Cl. CPC G11C 16/10; G11C 16/0483; G11C 16/08; G11C 16/24

(57) ABSTRACT

Example memory devices, memory systems, and methods for reducing time of program operation in NAND flash memory are disclosed. One example method includes programming a first memory cell in a first memory cell string of a memory cell array by applying a first programming voltage to a first word line coupled to the first memory cell string from a first time to a second time. A second programming voltage higher than or equal to the first programming voltage is applied to the first word line from the second time to a third time to program a second memory cell in a second memory cell string of the memory cell array, where the first word line is coupled to the second memory cell string.

### CROSS-REFERENCE TO RELATED APPLICATIONS

This application claims priority to Chinese Patent Application No. 202311292935.7, filed on Sep. 28, 2023, which is hereby incorporated by reference in its entirety.

### TECHNICAL FIELD

The present disclosure relates to memory devices, memory systems, and methods for program operations in a flash memory.

### BACKGROUND

Flash memory is a low-cost, high-density, nonvolatile solid-state storage medium that can be erased and programmed. Flash memory includes NOR flash memory and NAND flash memory. Various operations can be performed by a flash memory, for example, program (write) and erase operations, to change the threshold voltage of each memory cell to a respective level. For NAND flash memory, an erase operation can be performed at the block level, a program operation can be performed at the page level, and a read operation can be performed at the page level.

### SUMMARY

The present disclosure relates to memory devices, memory systems, and methods for reducing time of program operation in NAND flash memory. One example method includes programming a first memory cell in a first memory cell string of a memory cell array by applying a first programming voltage to a first word line coupled to the first memory cell string from a first time to a second time. A second programming voltage higher than or equal to the first programming voltage is applied to the first word line from the second time to a third time to program a second memory cell in a second memory cell string of the memory cell array, where the first word line is coupled to the second memory cell string.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates some example peripheral circuits, according to some aspects of the present disclosure.

FIG. 4 illustrates an example of voltage conditions of components in a memory cell array during programming of memory cells in multiple memory cell strings of the memory cell array, according to some aspects of the present disclosure.

FIG. 5 illustrates another example of voltage conditions of components in a memory cell array during programming of memory cells in multiple memory cell strings of the memory cell array, according to some aspects of the present disclosure.

FIG. 6 illustrates an example memory cell array with two memory cell strings, according to some aspects of the present disclosure.

FIG. 7 illustrates an example of a flow chart of a method for reducing time of program operation in a memory device, according to some aspects of the present disclosure.

FIG. 8 illustrates a block diagram of an example system having a memory device, according to some aspects of the present disclosure.

FIG. 9A illustrates a diagram of a memory card having a memory device, according to some aspects of the present disclosure.

FIG. 9B illustrates a diagram of a solid-state drive (SSD) having a memory device, according to some aspects of the present disclosure.

Like reference numbers and designations in the various drawings indicate like elements.

### DETAILED DESCRIPTION

This specification relates to memory devices, memory systems, methods, and media for reducing time of program operation in NAND flash memory. In some cases, a memory cell array can have multiple memory cell strings of memory cells. Each memory cell string can have memory cells corresponding to multiple cell columns. When memory cells in multiple memory cell strings are coupled to a word line and are selected for programming, a programming pulse can be applied to the word line, and a program operation of all the memory cells coupled to the word line and selected for programming can be performed within the programming pulse, without voltage ramp down being applied to the word line between programming of memory cells in different memory cell strings. Therefore, the time for programming the memory cells coupled to the word line can be reduced due to the elimination of applying voltage ramp down and ramp up to the word line between programming of memory cells in different memory cell strings.

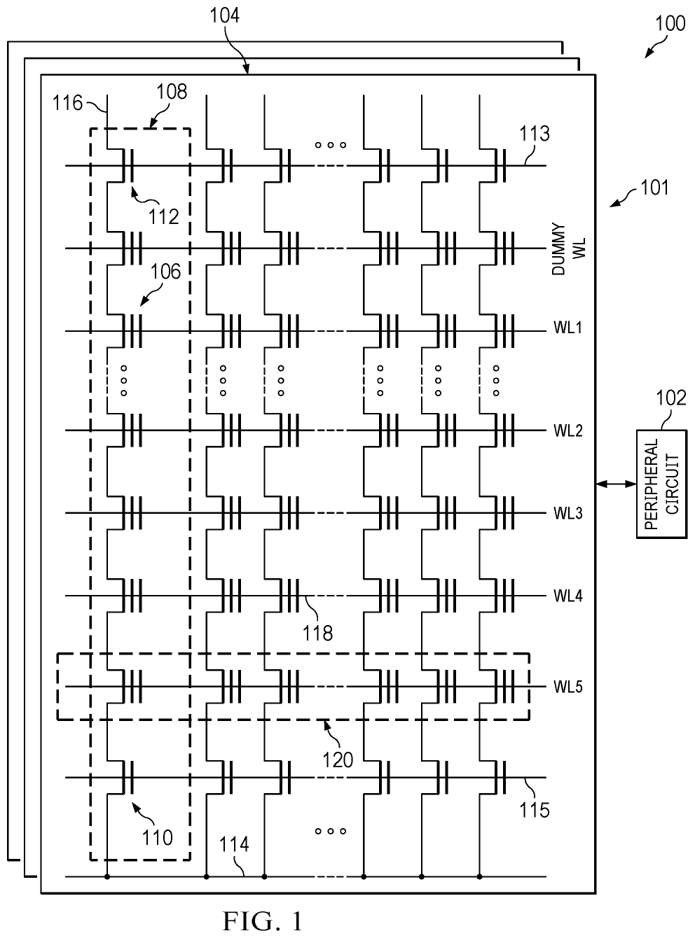

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., above the threshold voltage of the transistor having DSG 112) or a deselect voltage (e.g., 0 V) to respective DSG 112 through one or more DSG lines 113, and/or by applying a select voltage (e.g., above the threshold voltage of the transistor having SSG 110) or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 in respective page 120 and a gate line coupling the control gates. Example word lines shown in FIG. 1 include dummy WL, WL1, WL2, WL3, WL4, and WL5 that are between one or more DSG lines 113 and one or more SSG lines 115.

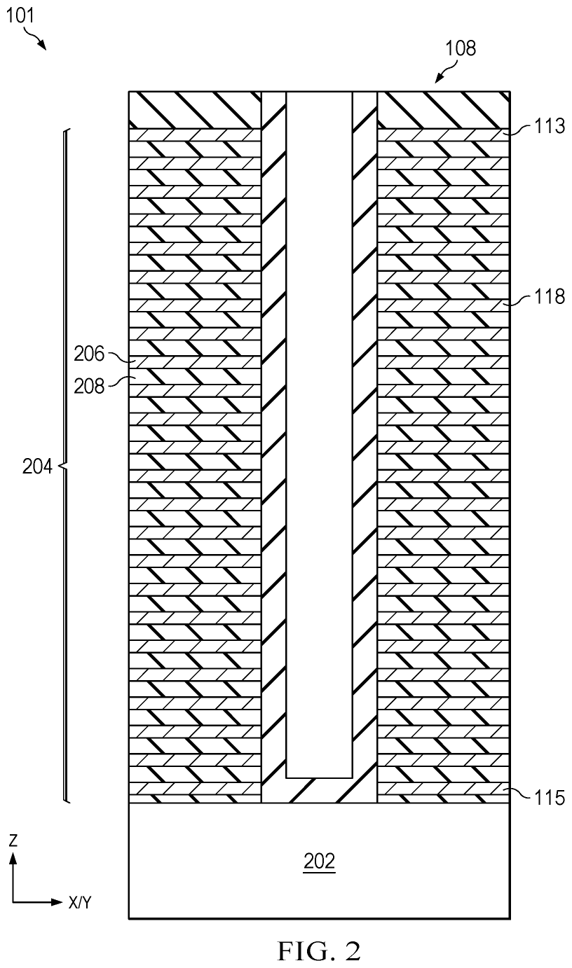

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

As shown in FIG. 1, consistent with the scope of the present disclosure, since a program operation is performed at the page/word line level for each block 104, each block 104 can be either an open block or a full block depending on whether all pages in respective block 104 have all been programmed. In some implementations, block 104 is an open block if at least one page 120 in block 104 is not programmed, i.e., memory cells 106 in at least one page 120 in block 104 are in the erased state. For example, an open block may include one or more unprogrammed pages. In some implementations, block 104 is a full block if all pages 120 in block 104 are programmed, i.e., memory cells 106 in all pages 120 in block 104 are in the programmed states. For example, a full block may not include any unprogrammed page.

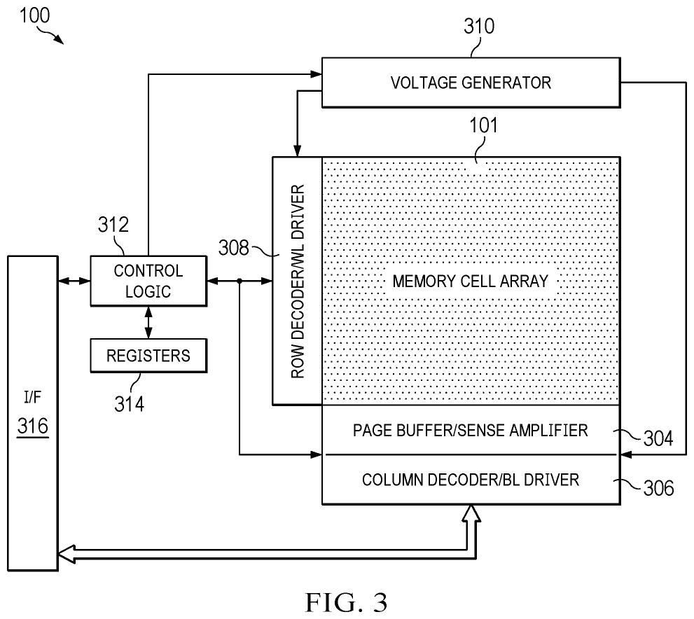

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page 120 of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. As described below in detail, row decoder/word line driver 308 is configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. As described below in detail, the status registers of registers 314 can include one or more registers configured to store open block information indicative of the open block(s) of all blocks 104 in memory cell array 101, such as having an ADSV list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

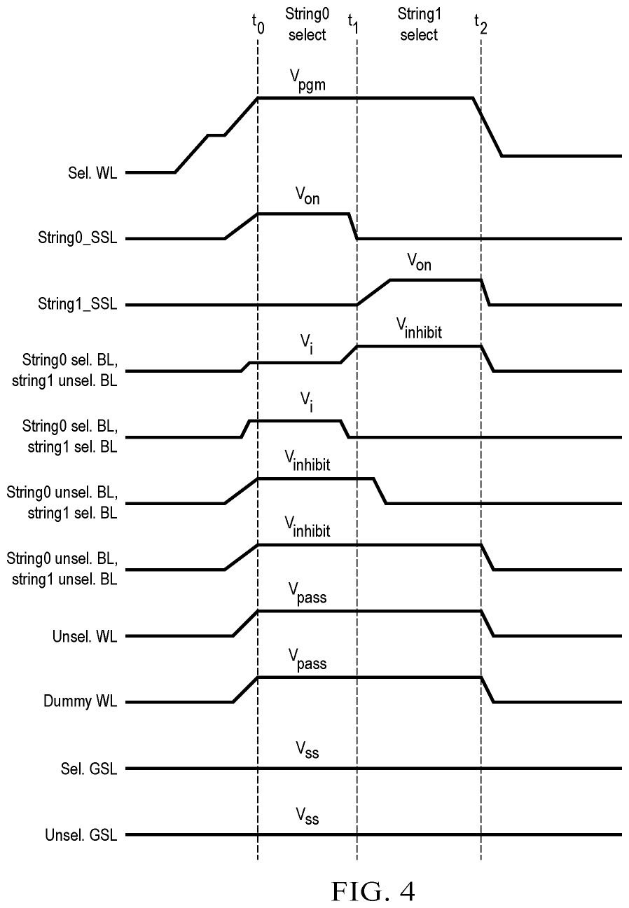

FIG. 4 illustrates an example of voltage conditions of components in a memory cell array during programming of memory cells in multiple memory cell strings of the memory cell array, according to some aspects of the present disclosure. In some implementations, select WL represents a word line (e.g., first word line) that is selected for a program operation of memory cells that are coupled to the word line and are in multiple memory cell strings of the memory cell array. Select WL can be an example of word line 118 in FIG. 1. Unselected WL represents a word line that is coupled to memory cells that are in multiple memory cell strings and are not selected for programming. Unselected WL can be an example of word line 118 in FIG. 1. Dummy WL represents a word line that is coupled to dummy memory cells in multiple memory cell strings. String0_SSL or string1_SSL represents one or more string select lines (SSLs), for example, DSG line 113 in FIG. 1, that are coupled to one or more select gate transistors, for example, DSG 112 in FIG. 1. Selected GSL or unselected GSL represents one or more ground select lines (GSLs), for example, SSG line 115, that are coupled to one or more select gate transistors, for example, SSG 110 in FIG. 1. Each of the four bit lines (BLs) with voltage conditions illustrated in FIG. 4 represents a bit line coupled to multiple cell columns in multiple memory cell strings of the memory cell array and can be an example of bit line 116 in FIG. 1.

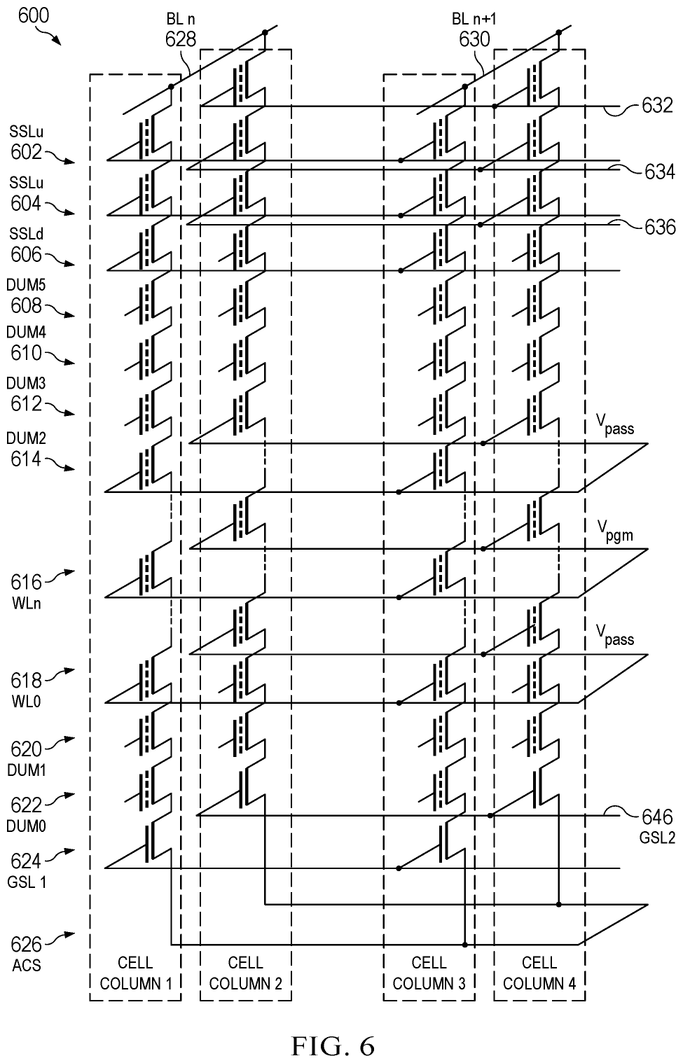

In some implementations, components with voltage conditions shown in FIG. 4 can be mapped to components in FIG. 6. FIG. 6 illustrates an example memory cell array 600 with two memory cell strings: string0 and string1, according to some aspects of the present disclosure. String0 includes memory cells associated with cell column 1 and cell column 3. String1 includes memory cells associated with cell column 2 and cell column 4. One or more memory cells in string0 that are coupled to a selected word line can be selected for programming during the time period from t₀ (e.g., first time) to t₁ (e.g., second time) in FIG. 4. Then during the time period from t₁ to t₂ (e.g., third time) in FIG. 4, one or more memory cells in string1 that are coupled to the selected word line can be selected for programming.

More specifically, in some implementations, to program the one or more memory cells in string0 from t₀ to t₁, a programming voltage (e.g., first programming voltage), for example, Vpgm applied to sel. WL in FIG. 4 from t₀ to t₁, can be applied to a selected word line coupled to both string0 and string1, for example, WLn 616 in FIG. 6 (corresponding to sel. WL in FIG. 4), from t₀ to t₁ in FIG. 4. The selected word line is coupled to the one or more memory cells in string0 that are selected for programming from t₀ to t₁.

In some implementations, after the one or more memory cells in string0 are programmed from t₀ to t₁, the one or more memory cells in string1 can be programmed from t₁ to t₂. To program the one or more memory cells in string1 from t₁ to t₂, a programming voltage (e.g., second programming voltage), for example, Vpgm applied to sel. WL in FIG. 4 from t₁ to t₂, can be applied to the selected word line coupled to both string0 and string1, for example, WLn 616 in FIG. 6 (corresponding to sel. WL in FIG. 4), from t₁ to t₂ in FIG. 4. The selected word line is coupled to the one or more memory cells in string1 that are selected for programming from t₁ to t₂. Therefore, by applying a programming voltage to the selected word line from t₁ to t₂ (to program the one or more memory cells in string1) immediately after applying a programming voltage to the selected word line from t₀ to t₁ (to program the one or more memory cells in string0), no voltage ramp down and the subsequent voltage ramp up are used between programming the one or more memory cells in string0 and programming the one or more memory cells in string1, and thus the total time used to program memory cells in both string0 and string1 can be reduced.

In some implementations, a pass voltage (e.g., fourth voltage), for example, Vpass applied to unsel. WL in FIG. 4 from t₀ to t₁, can be applied to unselected word lines (e.g., second word line), for example, WL0 618 in FIG. 6 (corresponding to unsel. WL in FIG. 4), from t₀ to t₁, when the one or more memory cells in string0 are programmed. The unselected word lines are coupled to memory cells in string0 and string1 that are not selected for programming from t₀ to t₁.

In some implementations, a pass voltage, for example, Vpass applied to unsel. WL in FIG. 4 from t₁ to t₂, can be applied to the unselected word lines, for example, WL0 618 in FIG. 6 (corresponding to unsel. WL in FIG. 4), from t₁ to t₂, when the one or more memory cells in string1 are programmed. The unselected word lines are coupled to memory cells in string0 and string1 that are not selected for programming from t₁ to t₂.

In some implementations, a pass voltage, for example, Vpass applied to dummy WL in FIG. 4 from t₀ to t₁, can be applied to dummy word lines, for example, dummy word lines 608, 610, 612, 614, 620, and 622 in FIG. 6 (corresponding to dummy WL in FIG. 4), from t₀ to t₁, when the one or more memory cells in string0 are programmed. The dummy word lines are coupled to dummy memory cells in string0 and string1.

In some implementations, a pass voltage, for example, Vpass applied to dummy WL in FIG. 4 from t₁ to t₂, can be applied to the dummy word lines, for example, dummy word lines 608, 610, 612, 614, 620, and 622 in FIG. 6 (corresponding to dummy WL in FIG. 4), from t₁ to t₂, when the one or more memory cells in string1 are programmed.

In some implementations, a turn-on voltage (e.g., first voltage), for example, Von applied to string0_SSL in FIG. 4 from t₀ to t₁, can be applied to one or more string select lines (e.g., first select line) that are coupled to string0 to turn on top select gate (TSG) transistors in string0, for example, TSG transistors in string0 that are coupled to string select lines 602, 604, and 606 respectively in FIG. 6, from t₀ to t₁, when the one or more memory cells in string0 are programmed. Examples of the one or more SSLs can include SSL 602 to SSL 606 in FIG. 6 (corresponding to string0_SSL in FIG. 4).

In some implementations, a turn-off voltage, for example, the voltage applied to string0_SSL in FIG. 4 from t₁ to t₂, can be applied to the one or more string select lines (SSLs) that are coupled to string0 to turn off memory cells in string0 from t₁ to t₂, when the one or more memory cells in string1 are programmed.

In some implementations, a turn-off voltage (e.g., second voltage), for example, Vss applied to string1_SSL in FIG. 4 from t₀ to t₁, can be applied to one or more SSLs (e.g., second select line) that are coupled to string1 to turn off TSG transistors in string1, for example, TSG transistors in string1 that are coupled to string select lines 632, 634, and 636 respectively in FIG. 6, from t₀ to t₁, when the one or more memory cells in string0 are programmed. Examples of the one or more SSLs can include SSL 632 to SSL 636 in FIG. 6 (corresponding to string1_SSL in FIG. 4). An example value of Vss is 0V.

In some implementations, a turn-on voltage, for example, Von applied to string1_SSL in FIG. 4 from t₁ to t₂, can be applied to one or more SSLs that are coupled to string1 to turn on memory cells in string1 from t₁ to t₂, when the one or more memory cells in string1 are programmed. Examples of the one or more SSLs can include SSL 632 to SSL 636 in FIG. 6 (corresponding to string1_SSL in FIG. 4). An example value of Vss is 0V. The turn-on voltage applied to the one or more SSLs coupled to string1 can be the same or different than the turn-on voltage applied to the one or more SSLs coupled to string0.

In some implementations, a voltage Vss (e.g., third voltage) can be applied to all ground select lines (GSLs) to ground them from t₀ to t₂. The grounded GSLs can include both GSLs (e.g., third select line) coupled to string0, for example, sel. GSL in FIG. 4, and GSLs (e.g., fourth select line) coupled to string1, for example, unsel. GSL in FIG. 4. Example GSLs coupled to string0 can include GSL1 624 in FIG. 6. Example GSLs coupled to string1 can include GSL2 646 in FIG. 6. An example value of Vss is 0V. In some implementations, ACS 626 can be coupled to multiple strings of a memory cell array.

In some implementations, a bit line can be coupled to multiple memory cell strings of a memory cell array. For example, BLn 628 in FIG. 6 is coupled to both memory cells in string0 that are associated with cell column 1 and memory cells in string1 that are associated with cell column 2. BLn+1 630 in FIG. 6 is coupled to both memory cells in string0 that are associated with cell column 3 and memory cells in string1 that are associated with cell column 4.

In some implementations, “string0 sel. BL, string1 unsel. BL” represents a bit line coupled to both a first cell column that is coupled to string0 and a second cell column that is coupled to string1. During the time period from t₀ to t₁, some memory cells associated with the first cell column are selected for programming. During the time period from t₁ to t₂, no memory cells associated with the second cell column are selected for programming. A voltage (e.g., fifth voltage), for example, Vi applied to “string0 sel. BL, string1 unsel. BL” in FIG. 4 from t₀ to t₁, can be applied to “string0 sel. BL, string1 unsel. BL” to reduce the speed of programming of memory cells that are coupled to “string0 sel. BL, string1 unsel. BL” and are in string0. The voltage Vi applied to “string0 sel. BL, string1 unsel. BL” can also turn on the TSGs that are coupled to “string0 sel. BL, string1 unsel. BL” and enable the memory cells coupled to “string0 sel. BL, string1 unsel. BL” to be programmed, although at a reduced speed. A voltage (e.g., sixth voltage), for example, Vinhibit applied to “string0 sel. BL, string1 unsel. BL” in FIG. 4 from t₁ to t₂, can be applied to “string0 sel. BL, string1 unsel. BL” from t₁ to t₂ to turn off the TSGs that are coupled to “string0 sel. BL, string1 unsel. BL” and to inhibit programming of memory cells that are coupled to “string0 sel. BL, string1 unsel. BL” and are in string1. Vi can be smaller than Vinhibit and larger than 0V. In some implementations, the voltage applied to “string0 sel. BL, string1 unsel. BL” can start to ramp up from Vi to Vinhibit a few microseconds earlier than t¹, which is the time when the voltage applied to string1_SSL starts to ramp up from the turn-off voltage (e.g., Vss) to the turn-on voltage (e.g., Von).

In some implementations, “string0 sel. BL, string1 sel. BL” represents a bit line coupled to both a first cell column that is coupled to string0 and a second cell column that is coupled to string1. During the time period from t₀ to t₁, some memory cells associated with the first cell column are selected for programming. During the time period from t₁ to t₂, some memory cells associated with the second cell column are selected for programming. A voltage (e.g., seventh voltage), for example, Vi applied to “string0 sel. BL, string1 sel. BL” in FIG. 4 from t₀ to t₁, can be applied to “string0 sel. BL, string1 sel. BL” to reduce the speed of programming of memory cells that are coupled to “string0 sel. BL, string1 sel. BL” and are in string0. A voltage lower than Vi, for example, Vss, can be applied to “string0 sel. BL, string1 sel. BL” from t₁ to t₂ to program memory cells that are coupled to “string0 sel. BL, string1 sel. BL” and are in string1. An example value of Vss is 0V.

In some implementations, “string0 unsel. BL, string1 sel. BL” represents a bit line coupled to both a first cell column that is coupled to string0 and a second cell column that is coupled to string1. During the time period from t₀ to t₁, no memory cells associated with the first cell column are selected for programming. During the time period from t₁ to t₂, some memory cells associated with the second cell column are selected for programming. A voltage (e.g., eighth voltage), for example, Vinhibit applied to “string0 unsel. BL, string1 sel. BL” in FIG. 4 from t₀ to t₁, can be applied to “string0 unsel. BL, string1 sel. BL” from t₀ to t₁ to inhibit programming of memory cells that are coupled to “string0 unsel. BL, string1 sel. BL” and are in string0. A voltage lower than Vi in FIG. 4, for example, Vss, can be applied to “string0 unsel. BL, string1 sel. BL” from t₁ to t₂ to program memory cells that are coupled to “string0 unsel. BL, string1 sel. BL” and are in string1. An example value of Vss is 0V. In some implementations, the voltage applied to “string0 unsel. BL, string1 sel. BL” can start to ramp down from Vinhibit to the voltage lower than Vi (e.g., Vss) a few microseconds after t¹, which is the time when the voltage applied to string0_SSL finishes ramping down from the turn-on voltage (e.g., Von) to the turn-off voltage (e.g., Vss).

In some implementations, “string0 unsel. BL, string1 unsel. BL” represents a bit line coupled to both a first cell column that is coupled to string0 and a second cell column that is coupled to string1. During the time period from t₀ to t₁, no memory cells associated with the first cell column are selected for programming. During the time period from t₁ to t₂, no memory cells associated with the second cell column are selected for programming. A voltage (e.g., ninth voltage), for example, Vinhibit applied to “string0 unsel. BL, string1 unsel. BL” in FIG. 4 from t₀ to t₁, can be applied to “string0 unsel. BL, string1 unsel. BL” from t₀ to t₁ to inhibit programming of memory cells that are coupled to “string0 unsel. BL, string1 unsel. BL” and are in string0. A voltage, for example, Vinhibit applied to “string0 unsel. BL, string1 unsel. BL” in FIG. 4 from t¹ to t₂, can be applied to “string0 unsel. BL, string1 unsel. BL” from t₁ to t₂ to inhibit programming of memory cells that are coupled to “string0 unsel. BL, string1 unsel. BL” and are in string1.

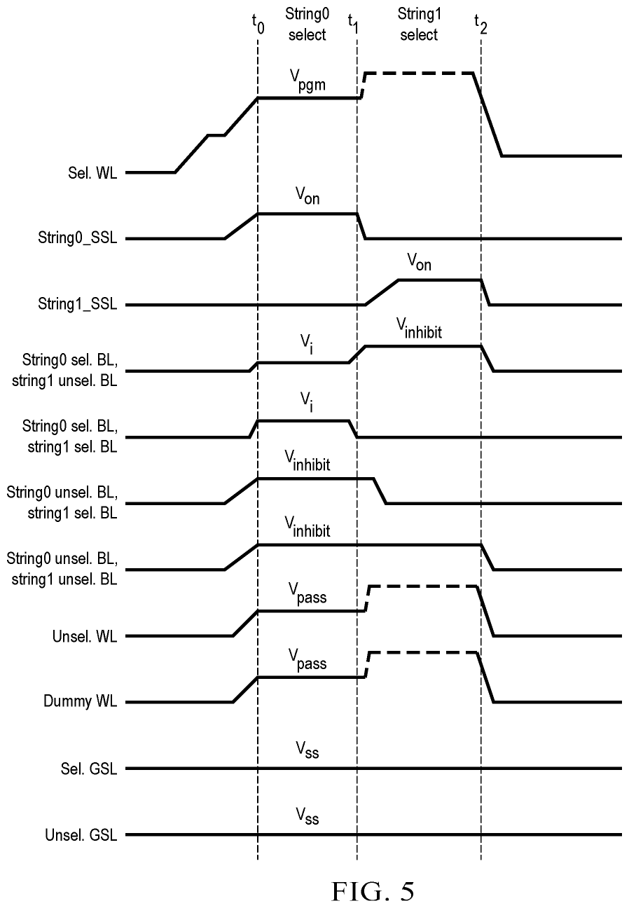

FIG. 5 illustrates another example of voltage conditions of components in a memory cell array during programming of memory cells in multiple memory cell strings of the memory cell array, according to some aspects of the present disclosure. Voltage conditions of most components in FIG. 5 are identical to their counterparts in FIG. 4, except for selected WL, unselected WL, and dummy WL. More specifically, because the voltage of each word line in FIG. 5 may ramp down when a memory cell string coupled to memory cells selected for programming is turned on and the channels corresponding to the memory cell string may discharge, an extra voltage can be applied to each word line when the memory cell string coupled to memory cells selected for programming is turned on. FIG. 5 shows the extra voltage applied to each word line when memory cells in string1 are selected for programming from t₁ to t₂.

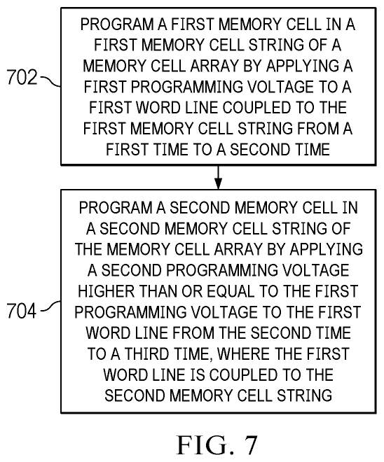

FIG. 7 illustrates an example of a flow chart of a method for reducing time of program operation in a memory device, according to some aspects of the present disclosure. At 702, a peripheral circuit of the memory device applies, at a first time and during a channel preparation period of a program operation of a first memory cell in the memory cell array, a first voltage to a first word line coupled to the first memory cell.

At 704, the peripheral circuit applies, at a second time after the first time and during the channel preparation period, a second voltage to the first word line, wherein the second voltage is lower than the first voltage.

At 706, the peripheral circuit applies a programming voltage to the first word line after the channel preparation period and during the program operation of the first memory cell.

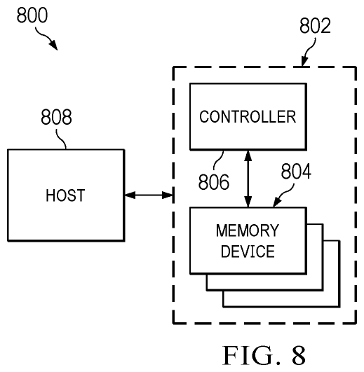

FIG. 8 illustrates a block diagram of an example system 800 having a memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more memory devices 804 and a memory controller 806. Host 808 can be a processor of an electronic device, such as a central processing unit (CPU), or a system-on-chip (SoC), such as an application processor (AP). Host 808 can be configured to send or receive data to or from memory devices 804.

Memory device 804 can be any memory device disclosed in the present disclosure. Memory controller 806 is coupled to memory device 804 and host 808 and is configured to control memory device 804, according to some implementations. Memory controller 806 can manage the data stored in memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of memory device 804, such as read, erase, and program operations. Memory controller 806 can also be configured to manage various functions with respect to the data stored or to be stored in memory device 804 including, but not limited to bad-block management, garbage collection, logical-to-physical address conversion, wear leveling, etc. In some implementations, memory controller 806 is further configured to process error correction codes (ECCs) with respect to the data read from or written to memory device 804. Any other suitable functions may be performed by memory controller 806 as well, for example, formatting memory device 804.

Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

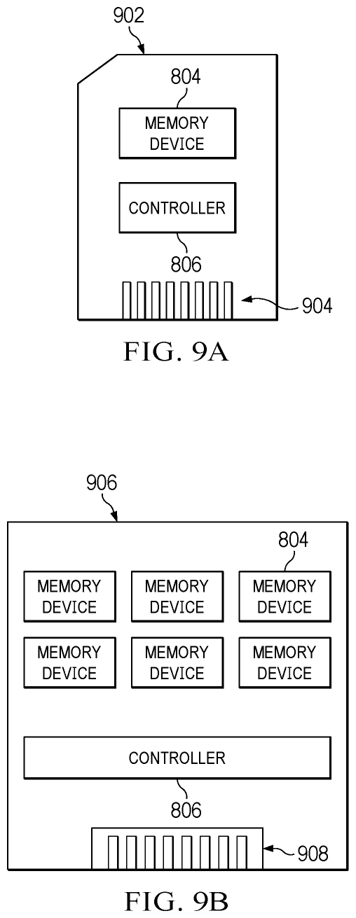

Memory controller 806 and one or more memory devices 804 can be integrated into various types of storage devices, for example, be included in the same package, such as a universal Flash storage (UFS) package or an eMMC package. That is, memory system 802 can be implemented and packaged into different types of end electronic products. In one example shown in FIG. 9A, memory controller 806 and a single memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 coupling memory card 902 with a host (e.g., host 808 in FIG. 8). In another example shown in FIG. 9B, memory controller 806 and multiple memory devices 804 may be integrated into an SSD 906. SSD 906 can further include an SSD connector 908 coupling SSD 906 with a host (e.g., host 808 in FIG. 8). In some implementations, the storage capacity and/or the operation speed of SSD 906 is greater than those of memory card 902.

Certain aspects of the subject matter described here can be implemented as a memory device. The memory device includes a memory cell array and a peripheral circuit. The memory cell array includes a plurality of memory cell strings coupled to a first word line, where each memory cell string of the plurality of memory cell strings includes a first select gate transistor, a second select gate transistor coupled to a source line of the memory cell array, and one or more memory cells positioned between the first select gate transistor and the second select gate transistor. The peripheral circuit is coupled to the memory cell array and configured to perform operations including programming a first memory cell in a first memory cell string of the plurality of memory cell strings by applying a first programming voltage to the first word line from a first time to a second time. The operations also include programming a second memory cell in a second memory cell string of the plurality of memory cell strings by applying a second programming voltage higher than or equal to the first programming voltage to the first word line from the second time to a third time.

The memory device can include one or more of the following features.

In some implementations, the operations further include applying, at the first time, a first voltage to a first select line coupled to a first select gate transistor of the first memory cell string, where the first voltage is lower than the first programming voltage, and applying, at the second time, a second voltage to the first select line, where the second voltage is lower than the first voltage.

In some implementations, the operations further include applying, at the first time, the second voltage to a second select line coupled to a first select gate transistor of the second memory cell string, and applying, at the second time, the first voltage to the second select line.

In some implementations, the operations further include applying, from the first time to the third time, a third voltage to a third select line coupled to a second select gate transistor of the first memory cell string, where the third voltage is lower than or equal to the second voltage.

In some implementations, the operations further include applying, from the first time to the third time, a third voltage to a fourth select line coupled to a second select gate transistor of the second memory cell string, where the third voltage is lower than or equal to the second voltage.

In some implementations, the operations further include applying, at the first time, a fifth voltage to a bit line coupled to the first memory cell string and the second memory cell string, and applying, between the first time and the second time, a sixth voltage to the bit line, where the sixth voltage is higher than the fifth voltage and lower than the first voltage.

In some implementations, the operations further include applying, at the first time, a fifth voltage to a bit line coupled to the first memory cell string and the second memory cell string, where the fifth voltage is lower than the first voltage, and applying, between the first time and the second time, a third voltage to the bit line, where the third voltage is lower than the fifth voltage.

In some implementations, the operations further include applying, at the first time, a sixth voltage to a bit line coupled to the first memory cell string and the second memory cell string, where the sixth voltage is lower than the first voltage, and applying, between the second time and the third time, a third voltage to the bit line, where the third voltage is lower than the sixth voltage.

In some implementations, the operations further include applying, at the first time, a sixth voltage to a bit line coupled to the first memory cell string and the second memory cell string, where the sixth voltage is lower than the first voltage, and applying, at the third time, a third voltage to the bit line, where the third voltage is lower than the sixth voltage.

In some implementations, the plurality of memory cell strings are coupled to a second word line, and the operations further include applying, at the first time, a fourth voltage to the second word line, where the fourth voltage is lower than the first programming voltage.

In some implementations, the plurality of memory cell strings are coupled to a dummy word line, and the operations further include applying, at the first time, the fourth voltage to the dummy word line.

In some implementations, the first memory cell and the second memory cell are single level cells (SLCs).

Certain aspects of the subject matter described here can be implemented as a memory system. The memory system includes a memory device and a controller. The memory device includes a memory cell array and a peripheral circuit. The memory cell array includes a plurality of memory cell strings coupled to a first word line, where each memory cell string of the plurality of memory cell strings includes a first select gate transistor, a second select gate transistor coupled to a source line of the memory cell array, and one or more memory cells positioned between the first select gate transistor and the second select gate transistor. The peripheral circuit is coupled to the memory cell array and configured to perform operations including programming a first memory cell in a first memory cell string of the plurality of memory cell strings by applying a first programming voltage to the first word line from a first time to a second time. The operations also include programming a second memory cell in a second memory cell string of the plurality of memory cell strings by applying a second programming voltage higher than or equal to the first programming voltage to the first word line from the second time to a third time. The controller is coupled to the memory device and configured to send a signal to the memory device to initiate the operations.

The memory system can include one or more of the following features.

In some implementations, the operations further include applying, at the first time, a first voltage to a first select line coupled to a first select gate transistor of the first memory cell string, where the first voltage is lower than the first programming voltage, and applying, at the second time, a second voltage to the first select line, where the second voltage is lower than the first voltage.

In some implementations, the operations further include applying, at the first time, the second voltage to a second select line coupled to a first select gate transistor of the second memory cell string, and applying, at the second time, the first voltage to the second select line.

In some implementations, the operations further include applying, at the first time, a fifth voltage to a bit line coupled to the first memory cell string and the second memory cell string, and applying, between the first time and the second time, a sixth voltage to the bit line, where the sixth voltage is higher than the fifth voltage and lower than the first voltage.

In some implementations, the operations further include applying, at the first time, a fifth voltage to a bit line coupled to the first memory cell string and the second memory cell string, where the fifth voltage is lower than the first voltage, and applying, between the first time and the second time, a third voltage to the bit line, where the third voltage is lower than the fifth voltage.

In some implementations, the operations further include applying, at the first time, a sixth voltage to a bit line coupled to the first memory cell string and the second memory cell string, where the sixth voltage is lower than the first voltage, and applying, between the second time and the third time, a third voltage to the bit line, where the third voltage is lower than the sixth voltage.

In some implementations, the operations further include applying, at the first time, a sixth voltage to a bit line coupled to the first memory cell string and the second memory cell string, where the sixth voltage is lower than the first voltage, and applying, at the third time, a third voltage to the bit line, where the third voltage is lower than the sixth voltage.

Certain aspects of the subject matter described here can be implemented as a method. The method includes programming a first memory cell in a first memory cell string of a memory cell array by applying a first programming voltage to a first word line coupled to the first memory cell string from a first time to a second time. A second memory cell in a second memory cell string of the memory cell array is programmed by application of a second programming voltage higher than or equal to the first programming voltage to the first word line from the second time to a third time, where the first word line is coupled to the second memory cell string.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory device, comprising:
a memory cell array comprising memory cell strings coupled to a first word line, wherein each memory cell string comprises a respective first select gate transistor, a respective second select gate transistor coupled to a source line of the memory cell array, and one or more respective memory cells positioned between the respective first select gate transistor and the respective second select gate transistor; and
a peripheral circuit coupled to the memory cell array and configured to perform operations comprising:
programming a first memory cell in a first memory cell string of the memory cell strings by applying a first programming voltage to the first word line from a first time to a second time; and
programming a second memory cell in a second memory cell string of the memory cell strings by applying a second programming voltage higher than or equal to the first programming voltage to the first word line from the second time to a third time.

2. The memory device according to claim 1, wherein the operations further comprise:
applying, at the first time, a first voltage to a first select line coupled to a first select gate transistor of the first memory cell string, wherein the first voltage is lower than the first programming voltage; and
applying, at the second time, a second voltage to the first select line, wherein the second voltage is lower than the first voltage.

3. The memory device according to claim 2, wherein the operations further comprise:
applying, at the first time, the second voltage to a second select line coupled to a first select gate transistor of the second memory cell string; and
applying, at the second time, the first voltage to the second select line.

4. The memory device according to claim 3, wherein the operations further comprise:
applying, from the first time to the third time, a third voltage to a third select line coupled to a second select gate transistor of the first memory cell string, wherein the third voltage is lower than or equal to the second voltage.

5. The memory device according to claim 3, wherein the operations further comprise:
applying, from the first time to the third time, a third voltage to a fourth select line coupled to a second select gate transistor of the second memory cell string, wherein the third voltage is lower than or equal to the second voltage.

6. The memory device according to claim 2, wherein the operations further comprise:
applying, at the first time, a fifth voltage to a bit line coupled to the first memory cell string and the second memory cell string; and
applying, between the first time and the second time, a sixth voltage to the bit line, wherein the sixth voltage is higher than the fifth voltage and lower than the first voltage.

7. The memory device according to claim 2, wherein the operations further comprise:
applying, at the first time, a seventh voltage to a bit line coupled to the first memory cell string and the second memory cell string, wherein the seventh voltage is lower than the first voltage; and
applying, between the first time and the second time, a third voltage to the bit line, wherein the third voltage is lower than the seventh voltage.

8. The memory device according to claim 2, wherein the operations further comprise:
applying, at the first time, an eighth voltage to a bit line coupled to the first memory cell string and the second memory cell string, wherein the eighth voltage is lower than the first voltage; and
applying, between the second time and the third time, a third voltage to the bit line, wherein the third voltage is lower than the eighth voltage.

9. The memory device according to claim 2, wherein the operations further comprise:
applying, at the first time, a ninth voltage to a bit line coupled to the first memory cell string and the second memory cell string, wherein the ninth voltage is lower than the first voltage; and
applying, at the third time, a third voltage to the bit line, wherein the third voltage is lower than the ninth voltage.

10. The memory device according to claim 1, wherein the memory cell strings are coupled to a second word line, and wherein the operations further comprise:
applying, at the first time, a fourth voltage to the second word line, wherein the fourth voltage is lower than the first programming voltage.

11. The memory device according to claim 10, wherein the memory cell strings are coupled to a dummy word line, and wherein the operations further comprise:
applying, at the first time, the fourth voltage to the dummy word line.

12. The memory device according to claim 1, wherein the first memory cell and the second memory cell are single level cells (SLCs).

13. A memory system, comprising:
a memory device, comprising:
a memory cell array comprising memory cell strings coupled to a first word line, wherein each memory cell string comprises a respective first select gate transistor, a respective second select gate transistor coupled to a source line of the memory cell array, and one or more respective memory cells positioned between the respective first select gate transistor and the respective second select gate transistor; and
a peripheral circuit coupled to the memory cell array and configured to perform operations comprising:
programming a first memory cell in a first memory cell string of the memory cell strings by applying a first programming voltage to the first word line from a first time to a second time; and
programming a second memory cell in a second memory cell string of the memory cell strings by applying a second programming voltage higher than or equal to the first programming voltage to the first word line from the second time to a third time; and
a controller coupled to the memory device and configured to send a signal to the memory device to initiate the operations.

14. The memory system according to claim 13, wherein the operations further comprise:
applying, at the first time, a first voltage to a first select line coupled to a first select gate transistor of the first memory cell string, wherein the first voltage is lower than the first programming voltage; and
applying, at the second time, a second voltage to the first select line, wherein the second voltage is lower than the first voltage.

15. The memory system according to claim 14, wherein the operations further comprise:
applying, at the first time, the second voltage to a second select line coupled to a first select gate transistor of the second memory cell string; and
applying, at the second time, the first voltage to the second select line.

16. The memory system according to claim 14, wherein the operations further comprise:
applying, at the first time, a fifth voltage to a bit line coupled to the first memory cell string and the second memory cell string; and
applying, between the first time and the second time, a sixth voltage to the bit line, wherein the sixth voltage is higher than the fifth voltage and lower than the first voltage.

17. The memory system according to claim 14, wherein the operations further comprise:
applying, at the first time, a seventh voltage to a bit line coupled to the first memory cell string and the second memory cell string, wherein the seventh voltage is lower than the first voltage; and
applying, between the first time and the second time, a third voltage to the bit line, wherein the third voltage is lower than the seventh voltage.

18. The memory system according to claim 14, wherein the operations further comprise:
applying, at the first time, an eighth voltage to a bit line coupled to the first memory cell string and the second memory cell string, wherein the eighth voltage is lower than the first voltage; and
applying, between the second time and the third time, a third voltage to the bit line, wherein the third voltage is lower than the eighth voltage.

19. The memory system according to claim 14, wherein the operations further comprise:
applying, at the first time, a ninth voltage to a bit line coupled to the first memory cell string and the second memory cell string, wherein the ninth voltage is lower than the first voltage; and
applying, at the third time, a third voltage to the bit line, wherein the third voltage is lower than the ninth voltage.

20. A method, comprising:
programming a first memory cell in a first memory cell string of a memory cell array by applying a first programming voltage to a first word line coupled to the first memory cell string from a first time to a second time; and
programming a second memory cell in a second memory cell string of the memory cell array by applying a second programming voltage higher than or equal to the first programming voltage to the first word line from the second time to a third time, wherein the first word line is coupled to the second memory cell string.
